(19) United States
(12) Patent Application Publication
(10) Pub. No.: US 2023/0179172 A1
(43) Pub. Date: Jun. 8, 2023

(54) ACOUSTIC RESONATOR FILTER AND ACOUSTIC RESONATOR PACKAGE

(71) Applicant: SAMSUNG ELECTRO-MECHANICS CO., LTD., Suwon-si (KR)

(72) Inventors: Dong Hoe KIM, Suwon-si (KR); Yoon Sok PARK, Suwon-si (KR)

(73) Assignee: SAMSUNG ELECTRO-MECHANICS CO., LTD., Suwon-si (KR)

(21) Appl. No.: 17/730,428

(22) Filed: Apr. 27, 2022

(30) Foreign Application Priority Data
Dec. 8, 2021 (KR) 10-2021-0174379

(51) Int. Cl. H03H 9/54; H03H 9/205

(52) U.S. Cl. CPC H03H 9/54; H03H 9/205

(57) ABSTRACT

An acoustic resonator filter includes: a series member including a plurality of series acoustic resonators electrically connected between a first radio frequency (RF) port and a second radio frequency port; and a shunt member including one or more shunt acoustic resonators electrically connected between the series member and a ground, wherein the plurality of series acoustic resonators are disposed to be anti-parallel to each other, and at least a portion of the first RF port includes a first connection via and a second connection via extending in a direction different from a direction in which the first connection via and the second connection via face the plurality of series acoustic resonators.

### CROSS-REFERENCE TO RELATED APPLICATIONS

This application claims the benefit under 35 USC § 119(a) of Korean Patent Application No. 10-2021-0174379, filed on Dec. 8, 2021, in the Korean Intellectual Property Office, the entire disclosure of which is incorporated herein by reference for all purposes.

### BACKGROUND

### 1. Field

The following description relates to an acoustic resonator filter and an acoustic resonator package.

### 2. Description of Related Art

Recently, in accordance with the rapid development of mobile communications devices, chemical and biological testing devices, and similar devices, the demand for a small and lightweight filter, oscillators, resonant elements, acoustic resonant mass sensors, and the like, implemented in such devices, has increased.

An acoustic resonator may be configured to implement the small and lightweight filter, the oscillator, the resonant element, and the acoustic resonant mass sensor, and may have a smaller size and better performance in comparison to a dielectric filter, a metal cavity filter, a wave guide, and the like. Therefore, it may be widely implemented in communications modules of modern mobile devices where excellent performance (for example, a high quality factor, small energy loss, and a wide pass bandwidth), are beneficial.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, an acoustic resonator includes a series member comprising a plurality of series acoustic resonators electrically connected between a first radio frequency (RF) port and a second radio frequency port; and a shunt member comprising one or more shunt acoustic resonators electrically connected between the series member and a ground, wherein the plurality of series acoustic resonators are disposed to be anti-parallel to each other, and wherein at least a portion of the first RF port comprises a first connection via and a second connection via extending in a direction different from a direction in which the first connection via and the second connection via face the plurality of series acoustic resonators.

Power of an RF signal passing through the first RF port may be greater than power of an RF signal passing through the second RF port, and the plurality of series acoustic resonators may be electrically connected at a position that is closer to the first RF port than to the second RF port.

The one or more shunt acoustic resonators may be a plurality of shunt acoustic resonators disposed to be anti-parallel to each other, and the plurality of shunt acoustic resonators are electrically connected to a third connection via and a fourth connection via extending in a direction different from a direction in which the respective third connection via and the fourth connection via face the plurality of shunt acoustic resonators.

The first connection via and the second connection via may be disposed electrically separate from each other.

Each of the plurality of series acoustic resonators may be a bulk acoustic resonator comprising a piezoelectric layer, a first electrode disposed below the piezoelectric layer, and a second electrode disposed on the piezoelectric layer, one of the first connection via and the second connection via may be electrically connected to the first electrode of a first of the plurality of series acoustic resonators, and another of the first connection via and the second connection via may be electrically connected to the second electrode of a second of the plurality of series acoustic resonators.

The acoustic resonator filter may further include a substrate disposed below the series member and the shunt member; and a cap disposed above the series member and the shunt member, wherein each of the first connection via and the second connection via is configured to penetrate through at least a portion of the substrate or at least a portion of the cap.

At least one of lengths or widths of metal layers connected between the plurality of series acoustic resonators and the first connection via and the second connection via, respectively, may be different from each other.

In a general aspect, an acoustic resonator package includes a substrate; a cap; a plurality of bulk acoustic resonators respectively comprising a first electrode, a piezoelectric layer, and a second electrode stacked in a direction in which the substrate and the cap face each other, and disposed between the substrate and the cap; a first metal layer of which at least a portion is connected to the first electrode of a first of the plurality of bulk acoustic resonators; a second metal layer of which at least a portion is connected to the second electrode of a second of the plurality of bulk acoustic resonators; a first connection via connected to at least a portion of the first metal layer and configured to penetrate through at least a portion of the substrate or at least a portion of the cap; and a second connection via connected to at least a portion of the second metal layer and configured to penetrate through at least a portion of the substrate or at least a portion of the cap, wherein at least one of a length and a width of a portion of the first metal layer connected between the first electrode of the first of the plurality of bulk acoustic resonators and the first connection via, and at least one of a length and a width of a portion of the second metal layer connected between the second electrode of the second of the plurality of bulk acoustic resonators and the second connection via are different from each other.

A difference between a resonance frequency between the second electrode of the first of the plurality of bulk acoustic resonators and the first connection via, and a resonance frequency between the first electrode of the second of the plurality of bulk acoustic resonators and the second connection via may be less than a difference between a resonance frequency between the first electrode and the second electrode of the first of the plurality of bulk acoustic resonators and a resonance frequency between the first electrode and the second electrode of the second of the plurality of bulk acoustic resonators.

The acoustic resonator package may include a first substrate wiring and a second substrate wiring disposed below the substrate, and electrically connected to the first connection via and the second connection via, respectively, wherein at least one of a length of the first substrate wiring, a length of the second substrate wiring, a width of the first substrate wiring, a width of the second substrate wiring, a distance between the first substrate wiring, and a ground, and a distance between the second substrate wiring and the ground may be different from each other.

The first of the plurality of bulk acoustic resonators may be electrically connected between the first connection via and an antenna, and wherein the second of the plurality of bulk acoustic resonators is electrically connected between the second connection via and the antenna.

The first connection via and the second connection via may be electrically separated from each other.

A resonance frequency of the plurality of series acoustic resonators may be greater than an anti-resonance frequency of the one or more shunt acoustic resonators.

In a general aspect, an acoustic resonator filter includes a plurality of series acoustic resonators electrically connected to a first connection via and a second connection, and disposed to be anti-parallel to each other; and a plurality of shunt acoustic resonators electrically connected to a third connection via and a fourth connection, and disposed to be anti-parallel to each other, wherein the first connection via and the second connection via are configured to extend in a direction different from a direction in which the first connection via and the second connection via face the plurality of series acoustic resonators.

Other features and aspects will be apparent from the following detailed description, the drawings, and the claims.

### BRIEF DESCRIPTION OF DRAWINGS

FIGS. 1A and 1B are circuit diagrams illustrating an example acoustic resonator filter, in accordance with one or more embodiments.

FIG. 2A is a plan view illustrating an example acoustic resonator filter, in accordance with one or more embodiments.

FIGS. 2B and 2C are plan views illustrating a plurality of example acoustic resonators disposed to be anti-parallel to each other in the acoustic resonator filter and an example acoustic resonator package, in accordance with one or more embodiments.

FIG. 3A is a graph illustrating a second harmonic of a structure in which a plurality of example series acoustic resonators disposed to be anti-parallel to each other are electrically connected to first and second connection vias, in accordance with one or more embodiments.

FIG. 3B is a graph illustrating a second harmonic of a structure in which the plurality of example series acoustic resonators disposed to be anti-parallel to each other are electrically connected to a common connection via, in accordance with one or more embodiments.

FIG. 4A is a perspective view illustrating an example acoustic resonator filter and an example acoustic resonator package, in accordance with one or more embodiments.

FIGS. 4B and 4C are a perspective view and a plan view illustrating wiring of an example electronic device substrate disposed below substrates of the acoustic resonator filter and the acoustic resonator package, in accordance with one or more embodiments.

FIG. 5A is a perspective view illustrating an example acoustic resonator package, in accordance with one or more embodiments.

FIG. 5B is a perspective view illustrating a structure in which an example acoustic resonator package is disposed on an example electronic device substrate, in accordance with one or more embodiments.

FIG. 6A is a plan view illustrating a specific structure of an example acoustic resonator that may be included in an example acoustic resonator package, in accordance with one or more embodiments. FIG. 6B is a cross-sectional view taken along line I-I′ of FIG. 6A, FIG. 6C is a cross-sectional view taken along line II-II′ of FIG. 6A, and FIG. 6D is a cross-sectional view taken along line III-III′ of FIG. 6A; and

FIGS. 6E and 6F are cross-sectional views illustrating a structure for connection between the inside and the outside of an example acoustic resonator package, in accordance with one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

Also, in the description of example embodiments, detailed description of structures or functions that are thereby known after an understanding of the disclosure of the present application will be omitted when it is deemed that such description will cause ambiguous interpretation of the example embodiments.

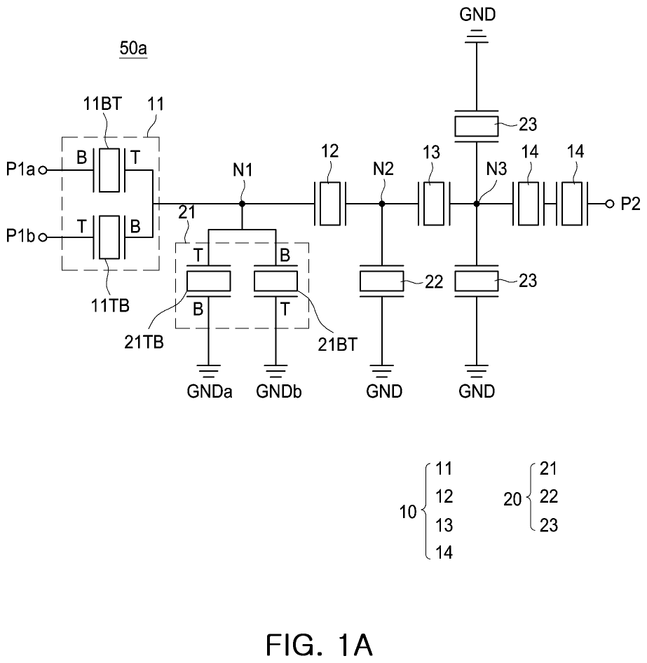

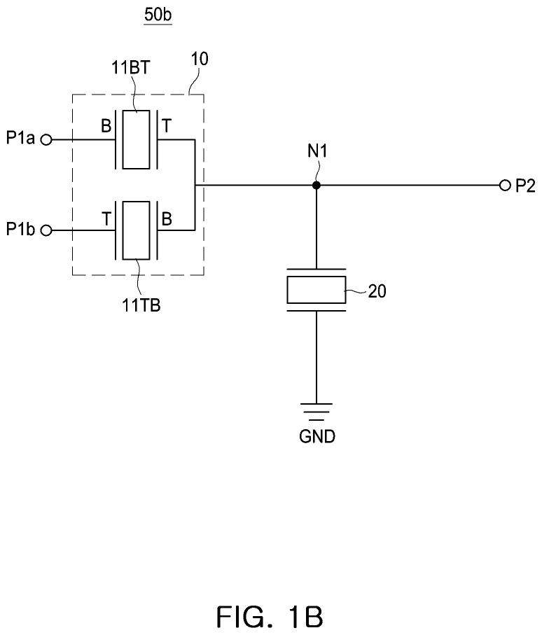

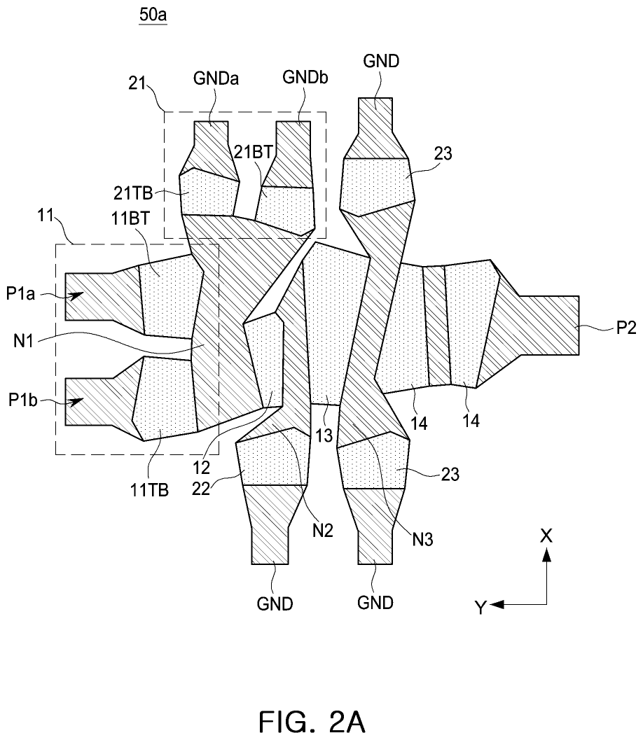

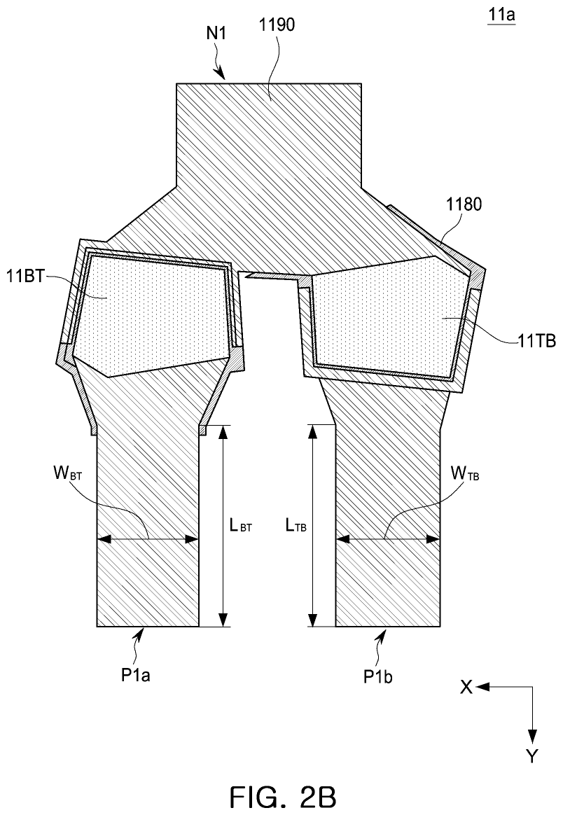

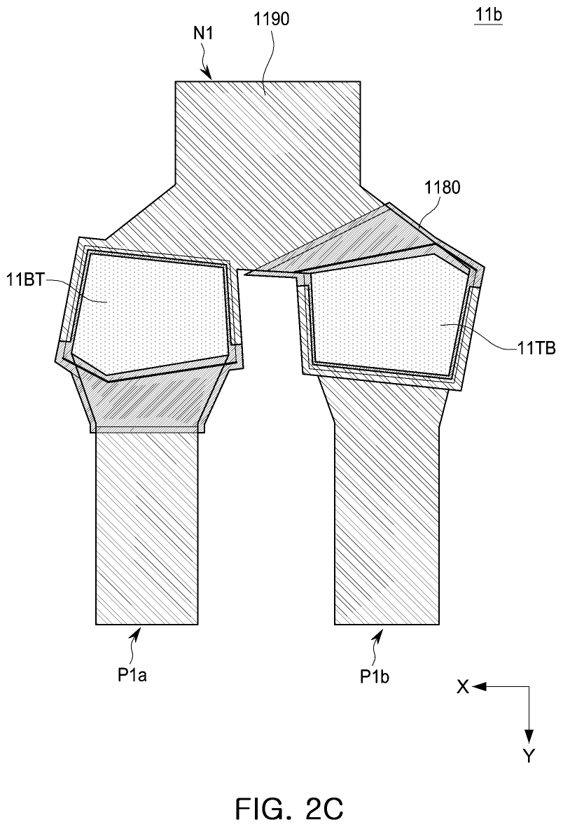

FIGS. 1A and 1B are circuit diagrams illustrating an example acoustic resonator filter, in accordance with one or more embodiments, and FIG. 2A is a plan view illustrating an example acoustic resonator filter, in accordance with one or more embodiments.

Referring to FIGS. 1A, 1B, and 2A, acoustic resonator filters 50a and 50b, in accordance with one or more embodiments, may each include a series member 10 and a shunt member 20, and may pass or block a radio frequency (RF) signal between a first RF port (including connection vias P1a and P1b) and a second RF port P2 according to a frequency of the RF signal. The first RF port may include first and second connection vias P1a and P1b. The first and second connection vias P1a and P1b and the second RF port P2 may be electrically connected to one or more series acoustic resonators 11, 12, 13, and 14 so that an external RF signal of the acoustic resonator filter 50a or 50b passes through one or more series acoustic resonators 11, 12, 13, and 14.

The series member 10 may include the one or more series acoustic resonators 11, 12, 13, and 14, and the shunt member 20 may include one or more shunt acoustic resonators 21, 22, and 23.

A plurality of nodes N1, N2, and N3 between the one or more series acoustic resonators 11, 12, 13, and 14, between the one or more shunt acoustic resonators 21, 22, and 23, and between the series member 10 and the shunt member 20 may be implemented as metal layers. The metal layer may be implemented with a material having a relatively low resistivity, such as gold (Au), a gold-tin (Au—Sn) alloy, copper (Cu), a copper-tin (Cu—Sn) alloy, aluminum (Al), or an aluminum alloy. However, the material of the metal layer is not limited thereto.

Each of the one or more series acoustic resonators 11, 12, 13, and 14 and the one or more shunt acoustic resonators 21, 22, and 23 may convert electrical energy of the RF signal into mechanical energy and perform inverse conversion with a piezoelectric property thereof. As the frequency of the RF signal is closer to a resonance frequency of the acoustic resonator, an energy transfer rate between a plurality of electrodes may be greatly increased. On the other hand, as the frequency of the RF signal is closer to an anti-resonance frequency of the acoustic resonator, the energy transfer rate between the plurality of electrodes may be greatly decreased. The anti-resonance frequency of the acoustic resonator may be higher than the resonance frequency of the acoustic resonator.

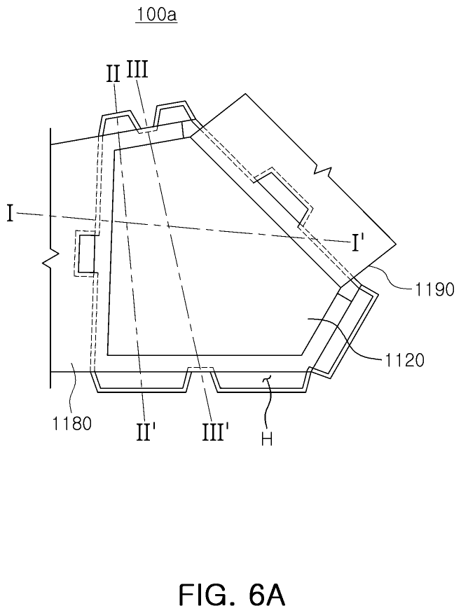

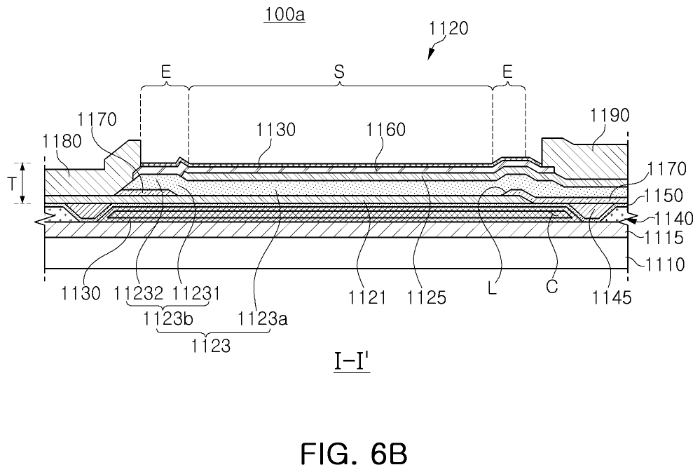

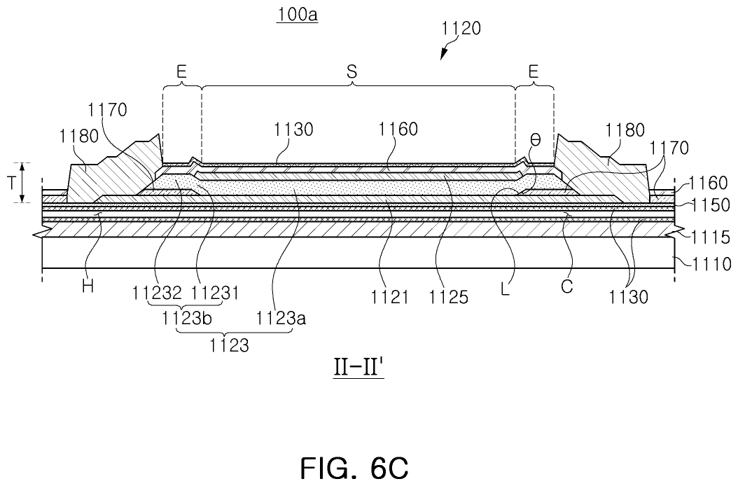

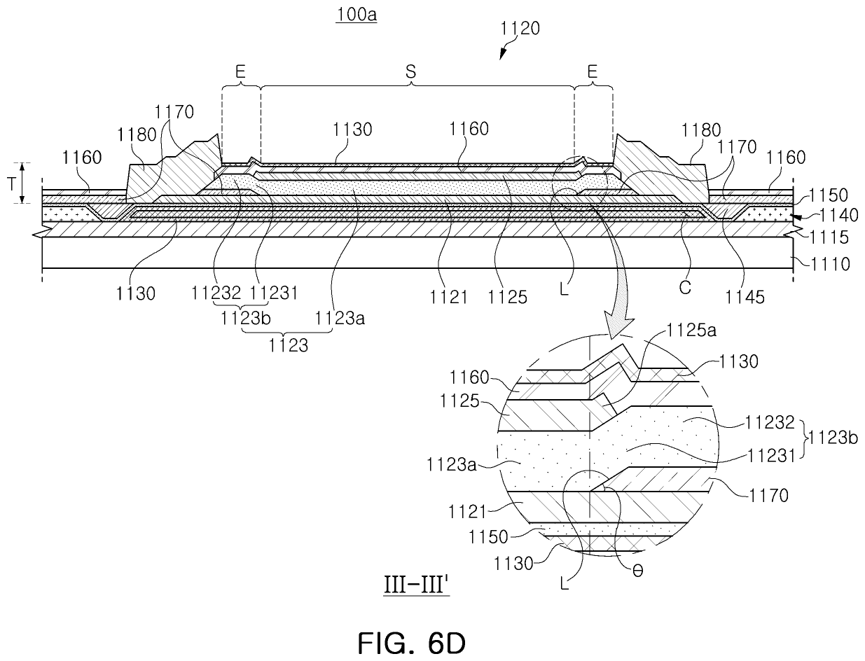

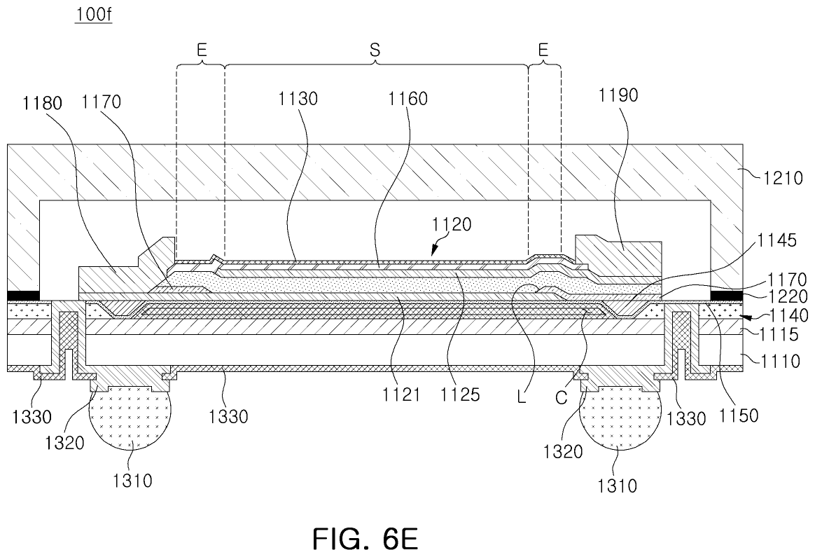

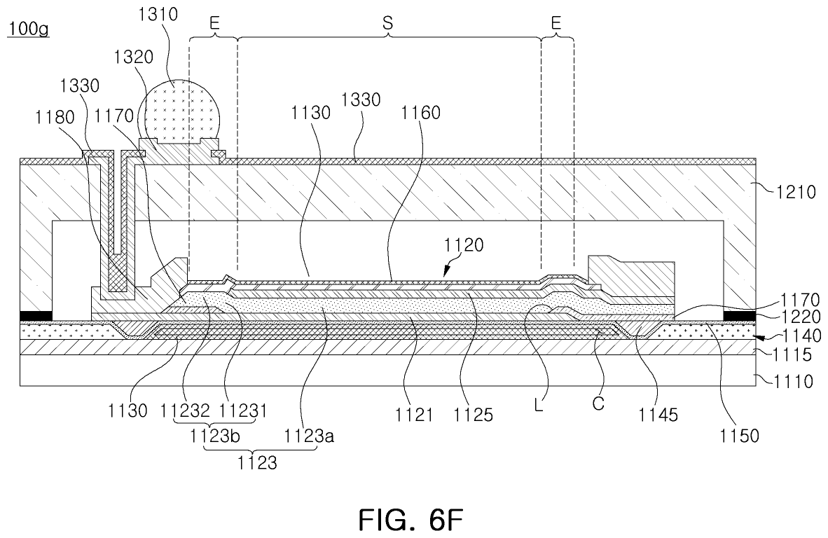

In an example, each of the one or more series acoustic resonators 11, 12, 13, and 14 and the one or more shunt acoustic resonators 21, 22, and 23 may be a bulk acoustic resonator or a surface acoustic resonator. The bulk acoustic resonator (see FIGS. 6A through 6F) may be a film bulk acoustic resonator (FBAR) or a solidly mounted resonator (SMR) type resonator.

The one or more series acoustic resonators 11, 12, 13, and 14 may be electrically connected in series between the first and second connection vias P1a and P1b and the second RF port P2. The closer the frequency of the RF signal to the resonance frequency, the higher the pass rate of the RF signal between the first and second connection vias P1a and P1b and the second RF port P2 may be. The closer the frequency of the RF signal to the anti-resonance frequency, the lower the pass rate between the first and second connection vias P1a and P1b and the second RF port P2 of the RF signal may be.

The one or more shunt acoustic resonators 21, 22, and 23 may be electrically shunt-connected between the one or more series acoustic resonators 11, 12, 13, and 14 and grounds GND (GNDa to GNDd), the closer the frequency of the RF signal to the resonance frequency, the higher the pass rate of the RF signal toward the ground GND may be, and the closer the frequency of the RF signal to the anti-resonance frequency, the lower the pass rate of the RF signal toward the ground GND may be.

The higher the pass rate of the RF signal toward the ground GND, the lower the pass rate of the RF signal between the first and second connection vias P1a and P1b and the second RF port P2 may be, and the lower the pass rate of the RF signal toward the ground GND, the higher the pass rate of the RF signal between the first and second connection vias P1a and P1b and the second RF port P2 may be.

That is, the closer the frequency of the RF signal to the resonance frequency of the one or more shunt acoustic resonators 21, 22, and 23 or to the anti-resonance frequency of the one or more series acoustic resonators 11, 12, 13, and 14, the lower the pass rate of the RF signal between the first and second connection vias P1a and P1b and the second RF port P2 may be.

Since the anti-resonance frequency may be higher than the resonance frequency, the acoustic resonator filters 50a and 50b may each have a pass bandwidth with the lowest frequency corresponding to the resonance frequency of the one or more shunt acoustic resonators 21, 22, and 23 and the highest frequency corresponding to the anti-resonance frequency of the one or more series acoustic resonators 11, 12, 13, and 14. Alternatively, the acoustic resonator filters 50a and 50b may include a stop bandwidth with the lowest frequency corresponding to the resonance frequency of the one or more series acoustic resonators 11, 12, 13, and 14 and the highest frequency corresponding to the anti-resonance frequency of the one or more shunt acoustic resonators 21, 22, and 23.

The larger the difference between the resonance frequency of the one or more shunt acoustic resonators 21, 22, and 23 and the anti-resonance frequency of the one or more series acoustic resonators 11, 12, 13, and 14, the wider the pass bandwidth may be. Further, the larger the difference between the resonance frequency of the one or more series acoustic resonators 11, 12, 13, and 14 and the anti-resonance frequency of the one or more shunt acoustic resonators 21, 22, and 23, the wider the stop bandwidth may be. However, in an example where the difference is excessively large, the bandwidth may be split, and an insertion loss and/or a return loss of the bandwidth may become large.

The resonance frequency of the one or more series acoustic resonators 11, 12, 13, and 14 may be adequately higher than the anti-resonance frequency of the one or more shunt acoustic resonators 21, 22, and 23, or the resonance frequency of the one or more shunt acoustic resonators 21, 22, and 23 may be adequately higher than the anti-resonance frequency of the one or more series acoustic resonators 11, 12, 13, and 14, a bandwidth of the acoustic resonator filters 50a and 50b may be wide and does not split, or the loss can be reduced.

In the acoustic resonator, the difference between the resonance frequency and the anti-resonance frequency may be determined based on an electromechanical coupling factor (kt²), which is a physical characteristic of the acoustic resonator, and kt² may be determined based on a size, a thickness, and a shape of the acoustic resonator. Depending on the implementation, the acoustic resonator filters 50a and 50b may each further include a passive component to have a frequency characteristic according to adjustment of kt² of some acoustic resonators.

Since the bandwidth of the acoustic resonator filters 50a and 50b may be proportional to general frequencies for the bandwidth, the higher the general frequencies for the bandwidth, the wider the bandwidth may be. However, the higher the general frequencies for the bandwidth, the shorter the wavelength of the RF signal passing through the acoustic resonator filters 50a and 50b may be. The shorter the wavelength of the RF signal, the greater the energy attenuation with respect to a transmission or reception distance in a remote transmission or reception process at an antenna may be. That is, the higher the general frequencies for the bandwidth of the acoustic resonator filters 50a and 50b, the greater power the RF signal passing through the acoustic resonator filters 50a and 50b may require in consideration of the energy attenuation in the remote transmission or reception process. In an example, the RF signal of a 5G communications standard uses a relatively higher frequency as compared to other communications standards (for example, LTE), and may be remotely transmitted through the antenna in a state of having power (for example, 26 dBm) higher than power (for example, 23 dBm) of other communications standards (for example, LTE).

As the power of the RF signal passing through the acoustic resonator filters 50a and 50b is increased, heat generated by a piezoelectric operation of each of the one or more shunt acoustic resonators 21, 22, and 23 and the one or more series acoustic resonators 11, 12, 13, and 14 and a possibility of damage due to the generated heat may be increased.

The series member 10 of each of the acoustic resonator filters 50a and 50b, in accordance with one or more embodiments, may include the plurality of series acoustic resonators 11 that are in an anti-parallel relationship. In an example, one 11BT of the plurality of series acoustic resonators 11 that are in the anti-parallel relationship may be connected to the first connection via P1a through a first electrode B disposed below a piezoelectric layer, and the other 11TB may be connected to the second connection via P1b through a second electrode T disposed on the piezoelectric layer.

Accordingly, the power of the RF signal passing through the plurality of series acoustic resonators 11 may be divided by the number of the plurality of series acoustic resonators 11, such that the power of the RF signal passing through each of the plurality of series acoustic resonators 11 may be reduced, and the heat generated by the piezoelectric operation of each of the plurality of series acoustic resonators 11 and the possibility of damage due to the generated heat may be reduced. Additionally, due to the anti-parallel relationship, an even-order harmonic of the RF signal passing through each of the plurality of series acoustic resonators 11 may be canceled at the node N1, and heat generated due to an energy bottleneck in the acoustic resonator filters 50a and 50b caused by the even-order harmonic and a possibility of damage due to the generated heat may be reduced, and linearity (for example, IMD2, IP2, P1dB, or THD) of the acoustic resonator filters 50a and 50b may be improved.

In one or more examples, a difference in parasitic impedance between the plurality of series acoustic resonators 11 that are in the anti-parallel relationship may act as a limit on efficiency in reducing the even-order harmonic of the RF signal.

The acoustic resonator filters 50a and 50b, in accordance with one or more embodiments, may each include the first and second connection vias P1a and P1b, thereby reducing the difference in parasitic impedance between the plurality of series acoustic resonators 11, and further increasing the efficiency in reducing the even-order harmonic of the RF signal. The first and second connection vias P1a and P1b included in the first RF port may be electrically connected to the plurality of series acoustic resonators 11, respectively, and may extend in a direction different from a direction in which the first and second connection vias P1a and P1b face the plurality of series acoustic resonators 11 (for example, a direction perpendicular to an X-Y plane).

Additionally, the first and second connection vias P1a and P1b may be portions through which the RF signal with the greatest power may pass in the acoustic resonator filters 50a and 50b, and may thus be portions where an effect of improving the efficiency in reducing the even-order harmonic is the most obvious. In an example, the second RF port P2 and the ground GND may also be replaced with a plurality of connection vias having a structure similar to those of the first and second connection vias P1a and P1b, but the effect of improving the efficiency in reducing the even-order harmonic may be relatively more obvious in the first and second connection vias P1a and P1b than in the second RF port P2 and the ground GND. The acoustic resonator filters 50a and 50b, in accordance with one or more embodiments, may reduce the even-order harmonic effectively for the total number of connection vias.

In an example, power of an RF signal passing through the first and second connection vias P1a and P1b included in the first RF port may be greater than power of an RF signal passing through the second RF port P2, and the plurality of series acoustic resonators 11 may be electrically connected closer to the first and second connection vias P1a and P1b than to the second RF port P2. Accordingly, the first and second connection vias P1a and P1b and the plurality of series acoustic resonators 11 may increase the efficiency in reducing the even-order harmonic.

Depending on the implementation, the plurality of shunt acoustic resonators 21 of the acoustic resonator filter 50a, in accordance with one or more embodiments, may be anti-parallel to each other, and may be electrically connected to third and fourth connection vias GNDa and GNDb extending in a direction different from a direction in which the third and fourth connection vias GNDa and GNDb face the plurality of shunt acoustic resonators 21. Accordingly, the even-order harmonic of the RF signal may be further reduced.

In an example, one 21TB of the plurality of shunt acoustic resonators 21 may be electrically connected to the third connection via GNDa through the first electrode B disposed below the piezoelectric layer, and the other 21BT may be electrically connected to the fourth connection via GNDb through the second electrode T disposed on the piezoelectric layer. Shapes of the third and fourth connection vias GNDa and GNDb may be similar to shapes of the first and second connection vias P1a and P1b.

FIGS. 2B and 2C are plan views illustrating the plurality of acoustic resonators disposed to be anti-parallel to each other in the acoustic resonator filter, and an acoustic resonator package, in accordance with one or more embodiments.

Referring to FIGS. 2B and 2C, one 11BT of the plurality of series acoustic resonators 11 that are anti-parallel to each other may be connected to a portion of a first metal layer 1180 through the first electrode, and the other 11TB may be connected to a first portion of a second metal layer 1190 through the second electrode.

In an example, the first portion of the second metal layer 1190 may be connected to the second connection via P1b, the portion of the first metal layer 1180 may be connected to a second portion of the second metal layer 1190, and the second portion of the second metal layer 1190 may be connected to the first connection via P1a. A third portion of the second metal layer 1190 may be connected to the plurality of series acoustic resonators 11 (11BT and 11TB), and may be a part of the node N1. The first, second, and third portions of the second metal layer 1190 may be spaced apart from one another.

At least one of lengths L_{BT} and L_{TB} or widths W_{BT} and W_{TB} of the first metal layer 1180 and/or the second metal layer 1190 connecting between the plurality of series acoustic resonators 11 (11BT and 11TB) and the first and second connection vias P1a and P1b, respectively, may be different from each other. Accordingly, the difference in parasitic impedance between the plurality of series acoustic resonators 11 (11BT and 11TB) may be further reduced, and thus the even-order harmonic of the RF signal may be further reduced.

In one or more examples, starting points of the lengths L_{BT} and L_{TB} may be the first and second connection vias P1a and P1b, respectively, and ending points may be one 11BT and the other 11TB of the plurality of series acoustic resonators. Additionally, the ending points may be set to critical points of a change in widths W_{BT} and W_{TB} as illustrated in FIG. 2B for measurement efficiency (in an example, measurement in a range in which the clarity of width measurement is increased). The widths W_{BT} and W_{TB} may be defined as average widths in a range in which the lengths L_{BT} and L_{TB} are measured. Specific measurement criteria for the lengths L_{BT} and L_{TB} and the widths W_{BT} and W_{TB} may be set to identify whether or not there is a difference between the lengths L_{BT} and L_{TB} or a difference between the widths W_{BT} and W_{TB} that is enough to effectively reduce the difference in parasitic impedance between one 11BT and the other 11TB of the plurality of series acoustic resonators.

In an example where the difference in parasitic impedance between one 11BT and the other 11TB of the plurality of series acoustic resonators is reduced, a difference between a resonance frequency between the second electrode of one 11BT of the plurality of series acoustic resonators and the first connection via P1a and a resonance frequency between the first electrode of the other 11TB and the second connection via P1b may become smaller than a difference between a resonance frequency between the first and second electrodes of one 11BT of the plurality of series acoustic resonators and a resonance frequency between the first and second electrodes of the other 11TB. Therefore, the measurement of the lengths L_{BT} and L_{TB} and the widths W_{BT} and W_{TB} may be replaced with resonance frequency measurement.

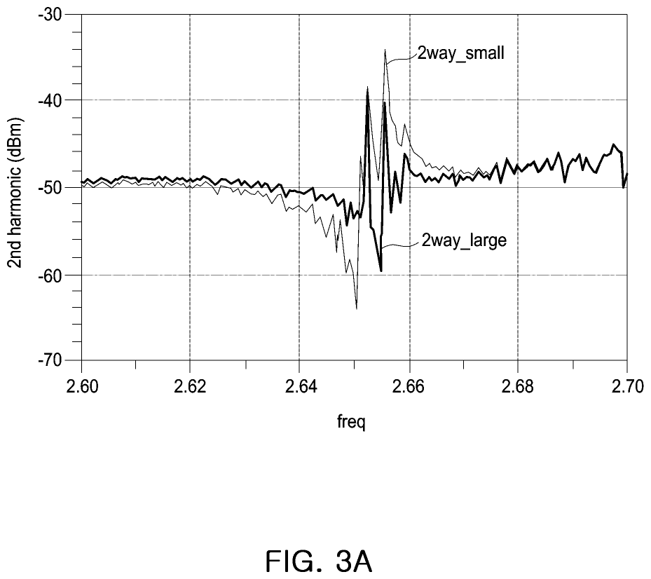

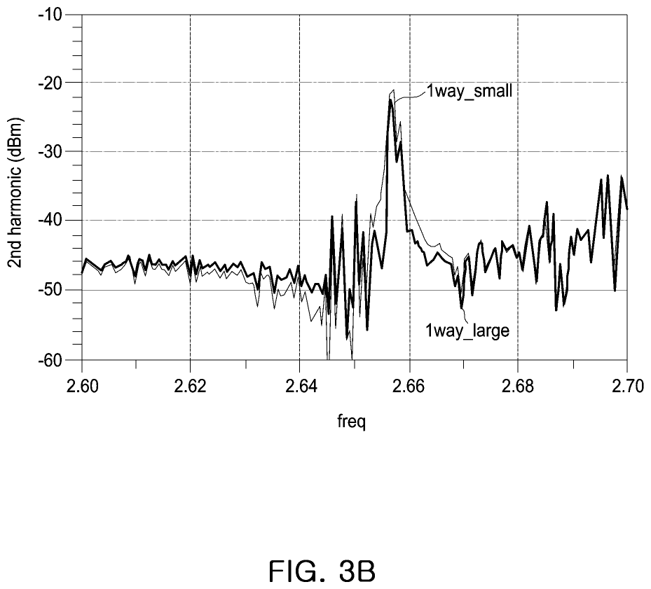

FIG. 3A is a graph illustrating a second harmonic of a structure in which the plurality of series acoustic resonators 11BT and 11TB, disposed to be anti-parallel to each other, are electrically connected to the first and second connection vias P1a and P1b, and FIG. 3B is a graph illustrating a second harmonic of a structure in which the plurality of series acoustic resonators, 11BT and 11TB, disposed to be anti-parallel to each other, are electrically connected to a common connection via.

Referring to FIGS. 3A and 3B, a maximum value and an average value of the second harmonic (2way_large and 2way_small) of the structure in which the plurality of series acoustic resonators, 11BT and 11TB, disposed to be anti-parallel to each other, are electrically connected to the first and second connection vias P1a and P1b may be about −40 dBm and −50 dBm, respectively, and a maximum value and an average value of the second harmonic (1way_large and 1way_small) of the structure in which the plurality of series acoustic resonators disposed to be anti-parallel to each other are electrically connected to the common connection via may be about −22 dBm and −46 dBm, respectively. The second harmonic of the acoustic resonator filter and the acoustic resonator package, in accordance with one or more embodiments, may be closer to the second harmonic (2way_large and 2way_small) of FIG. 3A, and may be lower than the second harmonic (1way_large and 1way_small) of FIG. 3B.

Meanwhile, an area of each of a plurality of series acoustic resonators with a second harmonic (2way_large and 1way_large) in the X-Y plane may be the square of about 100 microns, and an area of each of a plurality of series acoustic resonators with a second harmonic (2way_small and 1way_small) in the X-Y plane may be the square of about 70 microns. However, the areas are not limited thereto.

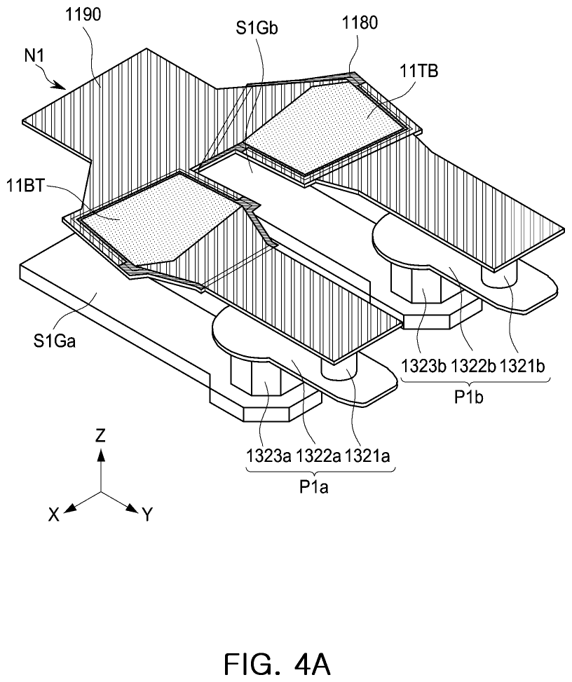

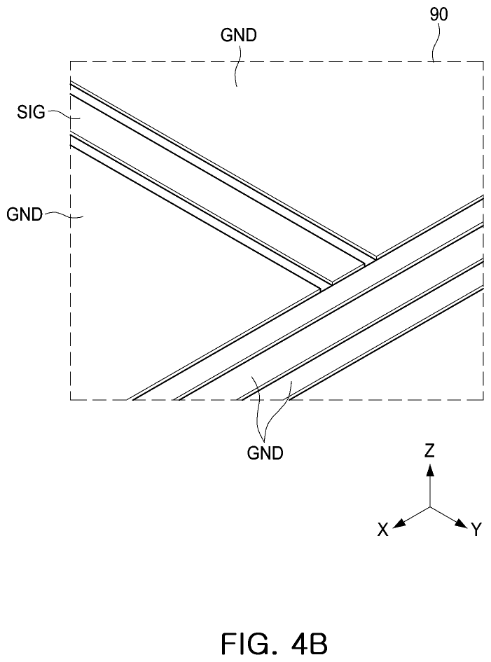

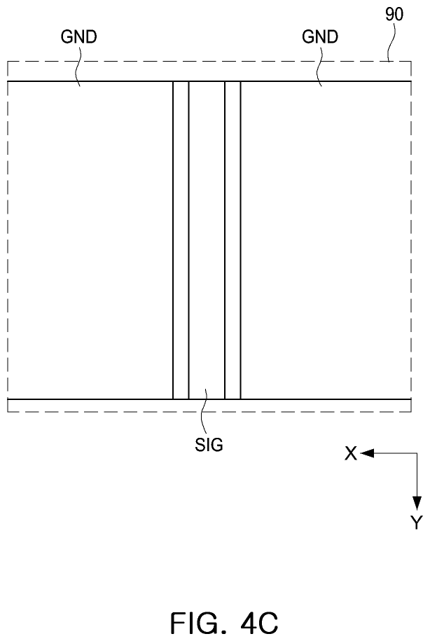

FIG. 4A is a perspective view illustrating the acoustic resonator filter and the acoustic resonator package, in accordance with one or more embodiments, and FIGS. 4B and 4C are a perspective view and a plan view illustrating wiring of an electronic device substrate disposed below substrates of the acoustic resonator filter and the acoustic resonator package, in accordance with one or more embodiments.

Referring to FIG. 4A, one 11BT and the other 11TB of the plurality of series acoustic resonators disposed to be anti-parallel to each other may be connected to the first and second connection vias P1a and P1b through at least a portion of the second metal layer 1190. Depending on an implementation, the plurality of series acoustic resonators may be a plurality of shunt acoustic resonators, and the second metal layer 1190 and the first metal layer 1180 may be interchanged with each other. Accordingly, in the acoustic resonator package, in accordance with one or more embodiments, the acoustic resonator may include the series acoustic resonator and/or the shunt acoustic resonator, and in the acoustic resonator package, in accordance with one or more embodiments, the metal layer may include the first metal layer 1180 and/or the second metal layer 1190.

In an example, the first connection via P1a may include at least one of a first interlayer via 1321a, a first via pad 1322a, or a third interlayer via 1323a, and the second connection via P1b may include at least one of a second interlayer via 1321b, a second via pad 1322b, or a fourth interlayer via 1323b. The first and second connection vias P1a and P1b may be spaced apart from each other.

In an example, the first connection via P1a may be electrically connected to a first substrate wiring S1Ga of the electronic device substrate, and the second connection via P1b may be electrically connected to a second substrate wiring S1Gb of the electronic device substrate. Since a range of the electronic device substrate may vary depending on the implementation, the first via pad 1322a and the third interlayer via 1323a may be parts of the electronic device substrate, and the second via pad 1322b and the fourth interlayer via 1323b may be parts of the electronic device substrate.

At least one of lengths of the first and second substrate wirings S1Ga and S1Gb, widths of the first and second substrate wirings S1Ga and S1Gb, or distances between the first and second substrate wirings S1Ga and S1Gb and the ground GND may be different from each other. Accordingly, the difference in parasitic impedance between one 11BT and the other 11TB of the plurality of series acoustic resonators 11 may be further reduced, and thus the even-order harmonic of the RF signal may be further reduced.

Referring to FIGS. 4B and 4C, the substrate wiring SIG may be one of the first and second substrate wirings of FIG. 4A, and may be surrounded by a ground layer providing the ground GND. The distance between the first or second substrate wiring S1Ga or S1Gb and the ground GND may be an average of a distance between the ground layer and the first or second substrate wiring S1Ga or S1Gb.

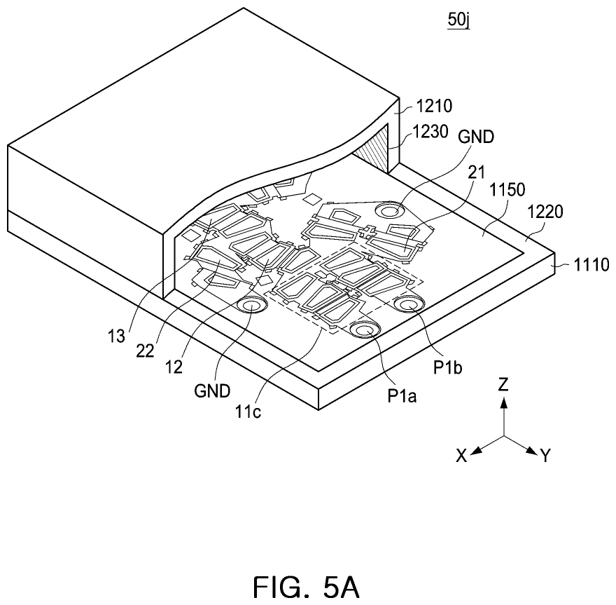

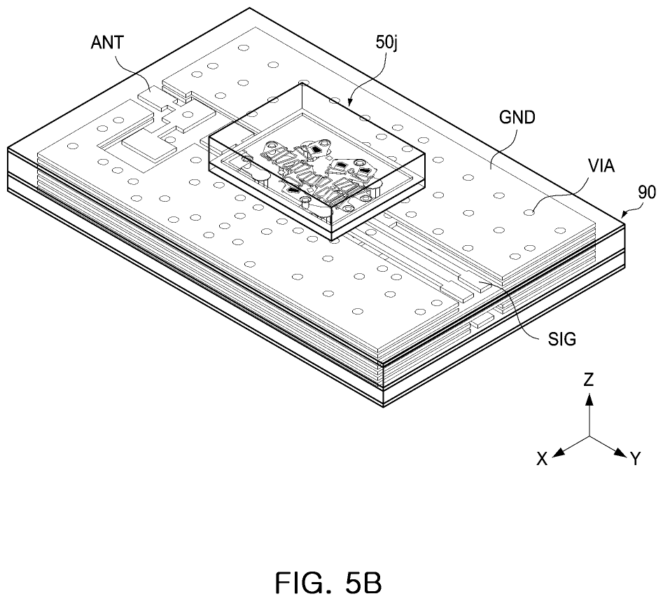

FIG. 5A is a perspective view illustrating the acoustic resonator package, in accordance with one or more embodiments, and FIG. 5B is a perspective view illustrating a structure in which the acoustic resonator package is disposed on the electronic device substrate, in accordance with one or more embodiments.

Referring to FIG. 5A, an acoustic resonator package 50j, in accordance with one or more embodiments, may include a substrate 1110 and a cap 1210, a plurality of bulk acoustic resonators 11c may be disposed between the substrate 1110 and the cap 1210, and a coupling member 1220 may provide a coupling force between the substrate 1110 and the cap 1210.

In an example, the cap 1210 may contain an insulating material such as glass or silicon, and the cap 1210 may have a U shape in a cross section perpendicular to the X-Y plane. Therefore, an outer periphery of the cap 1210 may protrude downward (for example, in a −Z direction) unlike the center of the cap 1210. Depending on an implementation, the cap 1210 may include a shield layer 1230 disposed on an inner surface, and the shield layer 1230 may be connected to the coupling member 1220. The shield layer 1230 may electromagnetically block an inner space surrounded by the cap 1210 and the outside of the cap 1210 from each other.

The inner space surrounded by the cap 1210 may be isolated from the outside of the cap 1210 as the cap 1210 is coupled to the substrate 1110. The coupling member 1220 may couple the cap 1210 and the substrate 1110 to each other, and in an example where an additional structure (for example, a membrane layer 1150) is disposed between the cap 1210 and the substrate 1110, at least one surface of the coupling member 1220 may be bonded to the additional structure to provide a coupling force between the cap 1210 and the substrate 1110.

The coupling member 1220 may provide the coupling force between the substrate and the cap. In an example, the coupling member 1220 may have a structure in which a plurality of conductive rings are eutectic-bonded, or an anodic bonding structure, may make a space between the substrate and the cap hermetic, and may isolate the space from the outside.

In an example, the coupling member 1220 may be disposed closer to the outer periphery than one or more series acoustic resonators 12 and 13 and one or more shunt acoustic resonators 21 and 22 are, may surround the one or more series acoustic resonators 12 and 13 and the one or more shunt acoustic resonators 21 and 22, and may be electrically connected to the ground. In a non-limiting example, each of the one or more series acoustic resonators 12 and 13 and the one or more shunt acoustic resonators 21 and 22 may be a bulk acoustic resonator.

The first and second connection vias P1a and P1b may be electrically connected to the plurality of bulk acoustic resonators 11c through the metal layer, and may penetrate through at least a portion of the substrate 1110 or at least a portion of the cap 1210.

Referring to FIG. 5B, the acoustic resonator package 50j, in accordance with one or more embodiments, may be mounted on, or embedded in, an electronic device substrate 90, may receive the RF signal through the substrate wiring SIG of the electronic device substrate 90, may filter the RF signal, and output the filtered RF signal to an antenna transmission line ANT. The electronic device substrate 90 may be a printed circuit board.

Since a difference in parasitic impedance between the plurality of bulk acoustic resonators 11c may be reduced by the length and/or width of the metal layer between the plurality of bulk acoustic resonators 11c and the first and second connection vias P1a and P1b, a difference between a resonance frequency between the second electrode of one of the plurality of bulk acoustic resonators 11c and the first connection via P1a, and a resonance frequency between the first electrode of the other of the plurality of bulk acoustic resonators 11c and the second connection via P1b may be smaller than a difference between a resonance frequency between the first and second electrodes of one of the plurality of bulk acoustic resonators 11c and a resonance frequency between the first and second electrodes of the other of the plurality of bulk acoustic resonators 11c.

The substrate wiring SIG and the antenna transmission line ANT may be electrically connected to a power amplifier and the antenna, respectively, and may be surrounded by the ground GND of the electronic device substrate 90. The ground GND included in the electronic device substrate 90 may be in a form of a plurality of plates connected to each other through a via VIA, and may be electrically connected to an electrical path different from the first and second RF ports of the acoustic resonator package 50j.

Referring to FIGS. 5A and 5B, one of the plurality of bulk acoustic resonators 11c may be electrically connected between the first connection via P1a and the antenna (electrically connected to the antenna transmission line ANT), and the other of the plurality of bulk acoustic resonators 11c may be electrically connected between the second connection via P1b and the antenna. Accordingly, the power of the RF signal passing through the acoustic resonator package 50j, in accordance with one or more embodiments, may be further increased, and the linearity of the RF signal may also be improved.

FIG. 6A is a plan view illustrating a specific structure of the bulk acoustic resonator that may be included in the acoustic resonator filter and the acoustic resonator package, in accordance with one or more embodiments, FIG. 6B is a cross-sectional view taken along line I-I′ of FIG. 6A, FIG. 6C is a cross-sectional view taken along line II-II′ of FIG. 6A, and FIG. 6D is a cross-sectional view taken along line III-III′ of FIG. 6A.

Referring to FIGS. 6A through 6D, a bulk acoustic resonator 100a may include a support substrate 1110, an insulating layer 1115, a resonance portion 1120, and a hydrophobic layer 1130.

The support substrate 1110 may be a silicon substrate. In an example, a silicon wafer or a silicon-on-insulator (SOI) type substrate may be used as the support substrate 1110.

An insulating layer 1115 may be provided on an upper surface of the support substrate 1110 to electrically isolate the support substrate 1110 from the resonance portion 1120 from each other. Additionally, the insulating layer 1115 may prevent the support substrate 1110 from being etched by an etching gas when a cavity C is formed in a process of manufacturing the bulk acoustic resonator.

In an example, the insulating layer 1115 may be formed of at least one of silicon dioxide (SiO₂), silicon nitride (Si₃N₄), aluminum oxide (Al₂O₃), or aluminum nitride (AlN), and may be formed by any one of chemical vapor deposition, RF magnetron sputtering, and evaporation.

The support layer 1140 may be formed on the insulating layer 1115 and may be disposed around the cavity C and an etch-stop portion 1145 so as to surround the cavity C and the etch-stop portion 1145.

The cavity C may be an empty space, and may be formed by partially removing a sacrificial layer in a process of forming the support layer 1140, and the support layer 1140 may be formed with the remaining portion of the sacrificial layer.

In an example, the support layer 1140 may be formed of a material such as polysilicon or polymer that is easy to etch, but the material of the support layer 1140 is not limited thereto.

The etch-stop portion 1145 may be disposed along a boundary of the cavity C. The etch-stop portion 1145 may be provided to prevent etching from being performed beyond a cavity region in a process of forming the cavity C.

The membrane layer 1150 may be formed on the support layer 1140 and form an upper surface of the cavity C. Therefore, the membrane layer 1150 may be formed of a material that is not easily removed in the process of forming the cavity C.

In an example where a halide-based etching gas such as fluorine (F) or chlorine (Cl) is used to remove a portion (for example, the cavity region) of the support layer 1140, the membrane layer 1150 may be formed of a material of which reactivity to the above-mentioned etching gas is low. In this example, the membrane layer 1150 may contain at least one of silicon dioxide (SiO₂) or silicon nitride (Si₃N₄).

Additionally, the membrane layer 1150 may be a dielectric layer containing at least one of magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), or zinc oxide (ZnO), or may be a metal layer containing at least one of aluminum (Al), nickel (Ni), chromium (Cr), platinum (Pt), gallium (Ga), or hafnium (Hf). However, a configuration of the examples is not limited thereto.

The resonance portion 1120 may include a first electrode 1121, a piezoelectric layer 1123, and a second electrode 1125. In the resonance portion 1120, the first electrode 1121, the piezoelectric layer 1123, and the second electrode 1125 may be sequentially stacked from below. Therefore, in the resonance portion 1120, the piezoelectric layer 1123 may be disposed between the first electrode 1121 and the second electrode 1125.

Since the resonance portion 1120 may be formed on the membrane layer 1150, the membrane layer 1150, the first electrode 1121, the piezoelectric layer 1123, and the second electrode 1125 may be sequentially stacked on the support substrate 1110 to form the resonance portion 1120.

The resonance portion 1120 may resonate the piezoelectric layer 1123 according to a signal applied to the first electrode 1121 and the second electrode 1125 to generate a resonance frequency and an anti-resonance frequency.

The resonance portion 1120 may be divided into a central portion S in which the first electrode 1121, the piezoelectric layer 1123, and the second electrode 1125 are approximately flatly stacked and an extension portion E in which an insertion layer 1170 is interposed between the first electrode 1121 and the piezoelectric layer 1123.

The central portion S may be a region disposed at the center of the resonance portion 1120, and the extension portion E may be a region disposed along a circumference of the central portion S. Therefore, the extension portion E may be a region extending outward from the central portion S, and may refer to a region formed in a continuous ring shape along the circumference of the central portion S. However, the extension portion E may also be formed in a discontinuous ring shape of which a partial region is cut.

Accordingly, as illustrated in FIG. 6B, in a cross section of the resonance portion 1120 across the central portion S, the extension portion E may be disposed at each of both ends of the central portion S. Additionally, the insertion layer 1170 may be disposed on each of both sides of the extension portion E disposed at each of both ends of the central portion S.

The insertion layer 1170 may have an inclined surface L whose thickness increases as the distance from the central portion S increases.

In the extension portion E, the piezoelectric layer 1123 and the second electrode 1125 may be disposed on the insertion layer 1170. Therefore, the piezoelectric layer 1123 and the second electrode 1125 positioned in the extension portion E may have inclined surfaces based on the shape of the insertion layer 1170.

In an example, the extension portion E may be implemented to be included in the resonance portion 1120, and thus, resonance may be achieved in the extension portion E as well. However, a position where the resonance is achieved is not limited thereto. That is, the resonance may not be achieved in the extension portion E and may be achieved only in the central portion S based on a structure of the extension portion E.

The first electrode 1121 and the second electrode 1125 may be formed of a conductor, for example, gold, molybdenum, ruthenium, iridium, aluminum, platinum, titanium, tungsten, palladium, tantalum, chromium, nickel, or a metal including at least one of them, but the material of the first electrode 1121 and the second electrode 1125 is not limited thereto.

In the resonance portion 1120, the first electrode 1121 may have an area larger than an area of the second electrode 1125, and the first metal layer 1180 may be disposed on the first electrode 1121 along an outer periphery of the first electrode 1121. Therefore, the first metal layer 1180 may be spaced apart from the second electrode 1125 by a predetermined distance, and may be disposed to surround the resonance portion 1120.

The first electrode 1121 may be disposed on the membrane layer 1150, and may thus be entirely flat. On the other hand, the second electrode 1125 may be disposed on the piezoelectric layer 1123, and may thus have a bend, or an incline, corresponding to a shape of the piezoelectric layer 1123.

The first electrode 1121 may be implemented as any one of an input electrode and an output electrode that respectively inputs and outputs an electrical signal such as an RF signal.

The second electrode 1125 may be mainly disposed in the central portion S, and may be partially disposed in the extension portion E. Therefore, the second electrode 1125 may be divided into a portion disposed on a piezoelectric portion 1123a of the piezoelectric layer 1123 to be described later and a portion disposed on a bent portion 1123b of the piezoelectric layer 1123.

More specifically, the second electrode 1125 may be disposed to cover the entire piezoelectric portion 1123a and a portion of an inclined portion 11231 of the piezoelectric layer 1123. Therefore, a portion (1125a of FIG. 6D) of the second electrode disposed in the extension portion E may have an area smaller than an area of an inclined surface of the inclined portion 11231, and the second electrode 1125 may have an area smaller than an area of the piezoelectric layer 1123 in the resonance portion 1120.

Accordingly, as illustrated in FIG. 6B, in a cross section of the resonance portion 1120 across the central portion S, an end of the second electrode 1125 may be disposed in the extension portion E. Further, the end of the second electrode 1125 disposed in the extension portion E may at least partially overlap with the insertion layer 1170. In an example, the overlapping means that when the second electrode 1125 is projected on a plane on which the insertion layer 1170 is disposed, the shape of the second electrode 1125 projected on the plane overlaps with the insertion layer 1170.

The second electrode 1125 may be used as any one of an input electrode and an output electrode that respectively inputs and outputs an electrical signal such as an RF signal. That is, in an example where the first electrode 1121 is used as the input electrode, the second electrode 1125 may be used as the output electrode, and in an example where the first electrode 1121 is used as the output electrode, the second electrode 1125 may be used as the input electrode.

In an example where the end of the second electrode 1125 is positioned on the inclined portion 11231 of the piezoelectric layer 1123 (to be described later) as illustrated in FIG. 6D, since a local structure of an acoustic impedance of the resonance portion 1120 is a sparse/dense/sparse/dense structure from the central portion S, a reflective interface reflecting a lateral wave inwardly of the resonance portion 120 may be increased. Therefore, most lateral waves may not flow outwardly of the resonance portion 120, and may be reflected inwardly of the resonance portion 120, such that the performance of the bulk acoustic resonator may be improved.

The piezoelectric layer 1123 may generate a piezoelectric effect that converts electrical energy into mechanical energy in a form of acoustic waves, and may be formed on the first electrode 1121 and the insertion layer 1170 to be described later.

Zinc oxide (ZnO), aluminum nitride (AlN), doped aluminum nitride, lead zirconate titanate, quartz, or the like, may be selectively used as a material of the piezoelectric layer 1123. The doped aluminum nitride may further include a rare earth metal, a transition metal, or an alkaline earth metal. The rare earth metal may include at least one of scandium (Sc), erbium (Er), yttrium (Y), or lanthanum (La). The transition metal may include at least one of hafnium (Hf), titanium (Ti), zirconium (Zr), tantalum (Ta), or niobium (Nb). The alkaline earth metal may include magnesium (Mg). Contents of elements doped into aluminum nitride (AlN) may be in a range of 0.1 to 30 at %.

The piezoelectric layer may be used by doping aluminum nitride (AlN) with scandium (Sc). In this example, a piezoelectric constant may be increased to increase Kt² of the bulk acoustic resonator.

The piezoelectric layer 1123 may include the piezoelectric portion 1123a disposed in the central portion S and the bent portion 1123b disposed in the extension portion E.

The piezoelectric portion 1123a may be a portion that is directly stacked on an upper surface of the first electrode 1121. Therefore, the piezoelectric portion 1123a may be interposed between the first electrode 1121 and the second electrode 1125, and may be formed to be flat together with the first electrode 1121 and the second electrode 1125.

The bent portion 1123b may refer to a region extending outward from the piezoelectric portion 1123a, and positioned in the extension portion E.

The bent portion 1123b may be disposed on the insertion layer 1170 to be described later, and an upper surface of the bent portion 1123b may protrude according to the shape of the insertion layer 1170. Therefore, the piezoelectric layer 1123 may be bent at a boundary between the piezoelectric portion 1123a and the bent portion 1123b, and the bent portion 1123b may protrude according to a thickness and the shape of the insertion layer 1170.

The bent portion 1123b may be divided into the inclined portion 11231 and an extending portion 11232.

The inclined portion 11231 may refer to a portion that is inclined along the inclined surface L of the insertion layer 1170 to be described later. Additionally, the extending portion 11232 may refer to a portion extending outward from the inclined portion 11231.

The inclined portion 11231 may be formed in parallel with the inclined surface L of the insertion layer 1170, and an inclined angle of the inclined portion 11231 may be the same as an inclined angle of the inclined surface L of the insertion layer 1170.

The insertion layer 1170 may be disposed along a surface formed by the membrane layer 1150, the first electrode 1121, and the etch-stop portion 1145. Accordingly, the insertion layer 1170 may be partially disposed in the resonance portion 1120, and may be disposed between the first electrode 1121 and the piezoelectric layer 1123.

The insertion layer 1170 may be disposed in the vicinity of the central portion S, and may support the bent portion 1123b of the piezoelectric layer 1123. Therefore, the bent portion 1123b of the piezoelectric layer 1123 may be divided into the inclined portion 11231 and the extending portion 11232 according to the shape of the insertion layer 1170.

The insertion layer 1170 may be disposed in a region except for the central portion S. In an example, the insertion layer 1170 may be disposed in the entire region except for the central portion S, or may be disposed in a partial region on the support substrate 1110.

The insertion layer 1170 may have a thickness that increases as the distance from the central portion S increases. Therefore, a side surface of the insertion layer 1170 that is disposed adjacent to the central portion S may be the inclined surface L having a predetermined inclined angle θ. The inclined angle θ of the inclined surface L may be in a range of 5° or more and 70° or less.

In an example, the inclined portion 11231 of the piezoelectric layer 1123 may be formed along the inclined surface L of the insertion layer 1170 and may have the same inclined angle as that of the inclined surface L of the insertion layer 1170. Accordingly, the inclined angle of the inclined portion 11231 may be in a range of 5° or more and 70° or less, similarly to the inclined surface L of the insertion layer 1170. It is a matter of course that the same configuration applies to the second electrode 1125 stacked on the inclined surface L of the insertion layer 1170.

The insertion layer 1170 may be formed of a dielectric material such as, but not limited to, silicon dioxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), or zinc oxide (ZnO), and may be formed of a material different from that of the piezoelectric layer 1123.

Additionally, the insertion layer 1170 may be implemented using a metal material. In an example where the bulk acoustic resonator is used for 5G communications, since a lot of heat is generated in the resonance portion, it is necessary to smoothly radiate the heat generated in the resonance portion 1120. To this end, the insertion layer 1170 may be formed of an aluminum alloy material containing scandium (Sc).

The resonance portion 1120 may be spaced apart from the support substrate 1110 through the cavity C that is an empty space.

The cavity C may be formed by partially removing the support layer 1140 with an etching gas (or an etching solution) supplied through an introduction hole (H in FIG. 6A) in a process of manufacturing the bulk acoustic resonator.

Therefore, the cavity C may be a space of which the upper surface (ceiling surface) and a side surface (wall surface) are formed by the membrane layer 1150, and a bottom surface is formed by the support substrate 1110 or the insulating layer 1115. Meanwhile, the membrane layer 1150 may form only the upper surface (ceiling surface) of the cavity C according to the order of a manufacturing method.

A protective layer 1160 may be disposed along a surface of the bulk acoustic resonator 100a to protect the bulk acoustic resonator 100a from external elements. The protective layer 1160 may be disposed along a surface formed by the second electrode 1125 and the bent portion 1123b of the piezoelectric layer 1123.

The protective layer 1160 may be partially removed for frequency control in a final process of the manufacturing process. In an example, a thickness of the protective layer 1160 may be adjusted through frequency trimming during the manufacturing process.

Accordingly, the protective layer 1160 may contain any one of, but not limited to, silicon dioxide (SiO₂), silicon nitride (Si₃N₄), magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), zinc oxide (ZnO), amorphous silicon (a-Si), and polycrystalline silicon (p-Si) that are suitable for frequency trimming, but is not limited thereto.

The first electrode 1121 and the second electrode 1125 may extend outward from the resonance portion 1120. Additionally, the first metal layer 1180 and the second metal layer 1190 may be disposed on upper surfaces of extending portions, respectively.

The first metal layer 1180 and the second metal layer 1190 may be formed of any one of materials such as, but not limited to, gold (Au), a gold-tin (Au—Sn) alloy, copper (Cu), a copper-tin (Cu—Sn) alloy, aluminum (Al), and an aluminum alloy. In the one or more examples, the aluminum alloy may be an aluminum-germanium (Al—Ge) alloy or an aluminum-scandium (Al—Sc) alloy.

The first metal layer 1180 and the second metal layer 1190 may be implemented as connection wirings electrically connecting the electrodes 1121 and 1125 of the bulk acoustic resonator and electrodes of another adjacent bulk acoustic resonator to each other on the support substrate 1110.

At least a portion of the first metal layer 1180 may be in contact with the protective layer 1160, and may be bonded to the first electrode 1121.

Further, in the resonance portion 1120, the first electrode 1121 may have a larger area than an area of the second electrode 1125, and the first metal layer 1180 may be formed on a circumferential portion of the first electrode 1121.

Therefore, the first metal layer 1180 may be disposed along a circumference of the resonance portion 1120 to thus surround the second electrode 1125. However, the disposition of the first metal layer 1180 is not limited thereto.

In the bulk acoustic resonator, the hydrophobic layer 1130 may be disposed on a surface of the protective layer 1160 and an inner wall of the cavity C. Since the hydrophobic layer 1130 may suppress the adsorption of water and hydroxyl groups (OH groups), frequency fluctuations may be significantly reduced, and thus, the performance of the resonator may be uniformly maintained.

The hydrophobic layer 1130 may be formed of a self-assembled monolayer (SAM) forming material rather than a polymer. In an example where the hydrophobic layer 1130 is formed of a polymer, a mass of the polymer may affect the resonance portion 1120. However, in the bulk acoustic resonator, since the hydrophobic layer 1130 may be formed of a self-assembled monolayer, fluctuations in resonance frequency of the bulk acoustic resonator may be significantly reduced. Additionally, a thickness of the hydrophobic layer 1130 according to a position in the cavity C may be uniform.

The hydrophobic layer 1130 may be formed by vapor-depositing a precursor that may have hydrophobicity. At this time, the hydrophobic layer 1130 may be deposited as a monolayer with a thickness of 100 A or less (for example, several A to several tens of A). The precursor that may have hydrophobicity may include a material whose contact angle with respect to water after deposition is 90 degrees or more. In an example, the hydrophobic layer 1130 may contain a fluorine (F) component and may contain fluorine (F) and silicon (Si). Specifically, fluorocarbon having a silicon head may be used, but the material of the hydrophobic layer 1130 is not limited thereto.

In an example, a bonding layer (not illustrated) may be formed on the surface of the protective layer 1160 prior to forming the hydrophobic layer 1130 in order to improve adhesion between the self-assembled monolayer forming the hydrophobic layer 1130 and the protective layer 1160.

The bonding layer may be formed by vapor-depositing a precursor having a hydrophobicity functional group on the surface of the protective layer 1160.

The precursor used for deposition of the bonding layer may be hydrocarbon having a silicon head or siloxane having a silicon head, but is not limited thereto.

Since the hydrophobic layer 1130 may be formed after the first metal layer 1180 and the second metal layer 1190 are formed, the hydrophobic layer 1130 may be formed along the surfaces of the protective layer 1160, the first metal layer 1180, and the second metal layer 1190.

In the drawings, an example in which the hydrophobic layer 1130 is not disposed on the surfaces of the first metal layer 1180 and the second metal layer 1190 is illustrated. However, the disposition of the hydrophobic layer 1130 is not limited thereto, and the hydrophobic layer 1130 may also be disposed on the surfaces of the first metal layer 1180 and the second metal layer 1190.

Additionally, the hydrophobic layer 1130 may be disposed on the inner surface of the cavity C as well as the upper surface of the protective layer 1160.

The hydrophobic layer 1130 formed in the cavity C may be formed on the entire inner wall forming the cavity C. Accordingly, the hydrophobic layer 1130 may be formed on a lower surface of the membrane layer 1150 forming a lower surface of the resonance portion 1120. In this example, adsorption of a hydroxyl group to a lower portion of the resonance portion 1120 may be suppressed.

The adsorption of a hydroxyl group may occur not only on the protective layer 1160 but also in the cavity C. Therefore, in order to significantly reduce mass loading due to the adsorption of a hydroxyl group and the consequent frequency drop, it is preferable to block the adsorption of a hydroxyl group not only on the protective layer 1160, but also on the upper surface of the cavity C, which is the lower surface of the resonance portion (the lower surface of the membrane layer).

Additionally, in an example where the hydrophobic layer 1130 is formed on the upper or lower surface or the side surface of the cavity C, an effect of suppressing a phenomenon (stiction phenomenon) in which the resonance portion 1120 sticks to the insulating layer 1115 by a surface tension in a wet process or cleaning process after the cavity C is formed may also be provided.

Although an example in which the hydrophobic layer 1130 is formed on the entire inner wall of the cavity C has been given as an example, the formation of the hydrophobic layer 1130 is not limited thereto, and various modifications are possible. For example, the hydrophobic layer 1130 may be formed only on the upper surface of the cavity C, or the hydrophobic layer 1130 may be formed on only at least portions of the lower surface and the side surface of the cavity C.

In an example, a thickness T of the bulk acoustic resonator 100a may be determined based on an implemented resonance frequency and/or anti-resonant frequency. In an example, the thickness T may be measured by analysis using at least one of, but not limited to, transmission electron microscopy (TEM), an atomic force microscope (AFM), a scanning electron microscope (SEM), an optical microscope, or a surface profiler.

FIGS. 6E and 6F are cross-sectional views illustrating a structure for connection between the inside and the outside of the acoustic resonator filter and the acoustic resonator package, in accordance with one or more embodiments.

Referring to FIGS. 6E and 6F, bulk acoustic resonators 100f and 100g may each further include at least one of a hydrophobic layer 1130, a bump 1310, a connection pattern 1320, or a hydrophobic layer 1330.

The hydrophobic layer 1130 may be disposed between the resonance portion 1120 and the cap 1210 and may be relatively more hydrophobic than the cap 1210. Accordingly, adsorption of organic matter, moisture, or the like that may be generated in a process of forming the coupling member 1220 to the resonance portion 1120 may be reduced, thereby further improving characteristics of the resonance portion 1120. In an example, the hydrophobic layer 1130 may be formed on an upper surface of the resonance portion 1120.

Referring to FIG. 6E, at least a portion of the connection pattern 1320 may penetrate through the substrate 1110, may be electrically connected to at least one of the first electrode 1121 or the second electrode 1125, and may be in contact with the hydrophobic layer 1330. Accordingly, the resonance portion 1120 may be electrically connected to the outside of the bulk acoustic resonator package.

The hydrophobic layer 1330 may be disposed on a surface (for example, a lower surface) of the substrate 1110 that is opposite to a surface (for example, an upper surface) facing the cap 1210 and may be relatively more hydrophobic than the substrate 1110. Accordingly, adsorption of organic matter, moisture, or the like that may be generated in the process of forming the coupling member 1220 to the connection pattern 1320 may be reduced, thereby further reducing transmission loss in the connection pattern 1320.

Referring to FIG. 6F, at least a portion of the connection pattern 1320 may penetrate through the cap 1210, may be electrically connected to at least one of the first electrode 1121 or the second electrode 1125, and may be in contact with the hydrophobic layer 1330. Accordingly, the resonance portion 1120 may be electrically connected to the outside of the bulk acoustic resonator package.

The hydrophobic layer 1330 may be disposed on a surface (for example, a lower surface) of the cap 1210 that is opposite to a surface (for example, an upper surface) facing the substrate 1110, and may be relatively more hydrophobic than the cap 1210. Accordingly, adsorption of organic matter, moisture, or the like that may be generated in the process of forming the coupling member 1220 to the connection pattern 1320 may be reduced, thereby further reducing transmission loss in the connection pattern 1320.

In an example, in a state in which the hole is formed in a portion of the substrate 1110 and/or the cap 1210, the connection pattern 1320 may be formed by depositing or applying a conductive metal (for example, gold, copper, or a titanium (Ti)-copper alloy) on a sidewall of the hole or by filling the hole with the conductive metal.

In an example, a process of forming the hole in the portion of the substrate 1110 and/or the cap 1210 may be omitted. In an example, the resonance portion 1120 may have an electrical connection path through wire bonding.

The bump 1310 may have a structure to support the bulk acoustic resonator 100f or 100g so that the bulk acoustic resonator 100f or 100g may be mounted on an external printed circuit board (PCB) positioned therebelow. For example, a portion of the connection pattern 1320 may be formed as a pad that is in contact with the bump 1310.

At least a portion of the connection pattern 1320 of FIGS. 6E and 6F may be at least one of the first, second, third, and fourth connection vias of the acoustic resonator filter and the acoustic resonator package, in accordance with one or more embodiments, or may be the second RF port.

As set forth above, in accordance with one or more embodiments, the acoustic resonator filter and the acoustic resonator package may efficiently reduce a harmonic of an RF signal, which may be advantageous in increasing power and/or frequency of the RF signal.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An acoustic resonator filter comprising:
a series member comprising a plurality of series acoustic resonators electrically connected between a first radio frequency (RF) port and a second radio frequency port; and
a shunt member comprising one or more shunt acoustic resonators electrically connected between the series member and a ground,
wherein the plurality of series acoustic resonators are disposed to be anti-parallel to each other, and
wherein at least a portion of the first RF port comprises a first connection via and a second connection via extending in a direction different from a direction in which the first connection via and the second connection via face the plurality of series acoustic resonators.

2. The acoustic resonator filter of claim 1, wherein power of an RF signal passing through the first RF port is greater than power of an RF signal passing through the second RF port, and
wherein the plurality of series acoustic resonators are electrically connected at a position that is closer to the first RF port than to the second RF port.

3. The acoustic resonator filter of claim 1, wherein the one or more shunt acoustic resonators are a plurality of shunt acoustic resonators disposed to be anti-parallel to each other, and
wherein the plurality of shunt acoustic resonators are electrically connected to a third connection via and a fourth connection via extending in a direction different from a direction in which the respective third connection via and the fourth connection via face the plurality of shunt acoustic resonators.

4. The acoustic resonator filter of claim 1, wherein the first connection via and the second connection via are disposed electrically separate from each other.

5. The acoustic resonator filter of claim 1, wherein each of the plurality of series acoustic resonators is a bulk acoustic resonator comprising a piezoelectric layer, a first electrode disposed below the piezoelectric layer, and a second electrode disposed on the piezoelectric layer,
wherein one of the first connection via and the second connection via is electrically connected to the first electrode of a first of the plurality of series acoustic resonators, and
wherein another of the first connection via and the second connection via is electrically connected to the second electrode of a second of the plurality of series acoustic resonators.

6. The acoustic resonator filter of claim 1, further comprising:
a substrate disposed below the series member and the shunt member; and
a cap disposed above the series member and the shunt member,
wherein each of the first connection via and the second connection via is configured to penetrate through at least a portion of the substrate or at least a portion of the cap.

7. The acoustic resonator filter of claim 1, wherein at least one of lengths or widths of metal layers connected between the plurality of series acoustic resonators and the first connection via and the second connection via, respectively, are different from each other.

8. The acoustic resonator filter of claim 1, wherein a resonance frequency of the plurality of series acoustic resonators is greater than an anti-resonance frequency of the one or more shunt acoustic resonators.

9. An acoustic resonator package comprising:
a substrate;
a cap;
a plurality of bulk acoustic resonators respectively comprising a first electrode, a piezoelectric layer, and a second electrode stacked in a direction in which the substrate and the cap face each other, and disposed between the substrate and the cap;
a first metal layer of which at least a portion is connected to the first electrode of a first of the plurality of bulk acoustic resonators;
a second metal layer of which at least a portion is connected to the second electrode of a second of the plurality of bulk acoustic resonators;
a first connection via connected to at least a portion of the first metal layer and configured to penetrate through at least a portion of the substrate or at least a portion of the cap; and
a second connection via connected to at least a portion of the second metal layer and configured to penetrate through at least a portion of the substrate or at least a portion of the cap,
wherein at least one of a length and a width of a portion of the first metal layer connected between the first electrode of the first of the plurality of bulk acoustic resonators and the first connection via, and at least one of a length and a width of a portion of the second metal layer connected between the second electrode of the second of the plurality of bulk acoustic resonators and the second connection via are different from each other.

10. The acoustic resonator package of claim 9, wherein a difference between a resonance frequency between the second electrode of the first of the plurality of bulk acoustic resonators and the first connection via, and a resonance frequency between the first electrode of the second of the plurality of bulk acoustic resonators and the second connection via is less than a difference between a resonance frequency between the first electrode and the second electrode of the first of the plurality of bulk acoustic resonators and a resonance frequency between the first electrode and the second electrode of the second of the plurality of bulk acoustic resonators.

11. The acoustic resonator package of claim 9, further comprising:
a first substrate wiring and a second substrate wiring disposed below the substrate, and electrically connected to the first connection via and the second connection via, respectively,
wherein at least one of a length of the first substrate wiring, a length of the second substrate wiring, a width of the first substrate wiring, a width of the second substrate wiring, a distance between the first substrate wiring, and a ground, and a distance between the second substrate wiring and the ground are different from each other.

12. The acoustic resonator package of claim 9, wherein the first of the plurality of bulk acoustic resonators is electrically connected between the first connection via and an antenna, and
wherein the second of the plurality of bulk acoustic resonators is electrically connected between the second connection via and the antenna.

13. The acoustic resonator package of claim 9, wherein the first connection via and the second connection via are electrically separated from each other.

14. An acoustic resonator filter comprising:
a plurality of series acoustic resonators electrically connected to a first connection via and a second connection, and disposed to be anti-parallel to each other; and
a plurality of shunt acoustic resonators electrically connected to a third connection via and a fourth connection, and disposed to be anti-parallel to each other,
wherein the first connection via and the second connection via are configured to extend in a direction different from a direction in which the first connection via and the second connection via face the plurality of series acoustic resonators.
